(19) United States
(12) Patent Application Publication
(10) Pub. No.: US 2006/0113897 A1
(43) Pub. Date: Jun. 1, 2006

(54) Light-emitting material, organic electroluminescent apparatus, and method of manufacturing the same

(75) Inventor: Akio Fukase, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/194,618

(22) Filed: Aug. 2, 2005

(30) Foreign Application Priority Data
Nov. 30, 2004 (JP) 2004-347203

(51) Int. Cl. H05B 33/10; H05B 33/14

(52) U.S. Cl. 313/504; 427/66

(57) ABSTRACT

A light-emitting material according to the present invention is a film-forming material used for film formation by a liquid-phase method and is a light-emitting material for forming a light-emitting layer. The light-emitting material, which is a solution, includes a plurality of film-forming components and a solvent for dissolving the film-forming components. The ratio of each of the film-forming components in the light-emitting layer to be formed is different, and each of the film-forming components is prepared with a ratio substantially equal to the desired ratio and is dissolved in the solvent. Saturated concentrations of the film-forming components in the solution at a predetermined temperature are different from each other corresponding to the difference in the desired ratio.

### BACKGROUND

The present invention relates to a light-emitting material which is suitable for forming a light-emitting layer in an organic electroluminescent apparatus, to a method of manufacturing an organic electroluminescent apparatus using the light-emitting material, and to an organic electroluminescent apparatus.

In recent years, as a self light-emitting-type display, organic electroluminescent elements (hereinafter, refers to as organic EL elements) have been developed. The organic EL elements are constructed so that a thin film made of an organic material is interposed between first and second electrodes, and carriers injected from the two electrodes are re-coupled in the organic thin film, thereby realizing light-emission.

The organic EL apparatus including a plurality of organic EL elements having the above-mentioned structure has characteristics such as small thickness and low weight. Further, when application and film formation are performed by a liquid-phase method represented by the inkjet method disclosed in Japanese Unexamined Patent Application Publication No. 2004-140004, it is possible to uniformly form the organic thin film over a wide area. Therefore, it can be expected to be applied to large-sized flat panel displays.

Further, recently, a highly efficient organic EL element which is used for emitting phosphorescence caused by a triplet excited state of a light-emitting material has been suggested, and it is expected to be applied to displays in which the power consumption is relatively small. The light-emitting material, which can emit phosphorescence, that is, a phosphorescent material, is generally a mixed two-component system including a host material with a carrier transport function and a guest material with a phosphorescence emitting function. Therefore, when the light-emitting layer is made of the phosphorescent material, the host material and the guest material need to be uniformly mixed.

However, when the light-emitting layer is formed of the phosphorescent material, which is the mixed two-component system, by the liquid-phase method, problems occur, such as those described below.

In a case where the film formation is performed by using a material of a two-component system composed of two different materials (solutes), first, the two different materials need to be dissolved in one solvent. Next, the solution obtained by dissolving the two materials (solutes) into the one solvent is disposed at desirable places such as pixels, and then the solvent is dried, such that the materials (solutes) are deposited, whereby a film is formed.

However, in the obtained film, the two solutes (components) need to be deposited simultaneously at a predetermined temperature, for example, a drying temperature, to uniformly mix the two different components (materials). When they are deposited at various times and not simultaneously, the two solutes (components) exist but unevenly, for example, depending on the position inside a pixel, thereby causing phase separation. As a result, it is difficult to obtain suitable light-emission.

### SUMMARY

An advantage of the invention is that it provides a light-emitting material capable of forming a light-emitting layer in which a plurality of components is uniformly mixed in a desirable ratio without the occurrence of phase separation, a method of manufacturing an organic EL apparatus using the light-emitting material, and an organic EL apparatus.

The light-emitting material according to the present invention is a film-forming material used for film formation by a liquid-phase method and is a light-emitting material for forming a light-emitting layer. The light-emitting material, which is a solution, includes a plurality of film-forming components and a solvent for dissolving the film-forming components. The ratio of each of the film-forming components in the light-emitting layer to be formed is different, and each of the film-forming components is prepared with a ratio substantially equal to the desired ratio and is dissolved in the solvent. Saturated concentrations of the film-forming components in the solution at a predetermined temperature are different from each other corresponding to the difference in the desired ratio.

According to such light-emitting material, since each of the film-forming components is prepared with a ratio substantially equal to the desired ratio and is dissolved in the solvent to form the solution, for example, when the solution (light-emitting material) is dried at the determined temperature, each of the film-forming components in the solution reaches the saturated concentration virtually simultaneously. At this time, the saturated concentration of each of the film-forming components at the predetermined temperature of the solution is different corresponding to the difference in the desired ratio of each of the film forming components in the light-emitting layer to be formed, such that each of the film-forming components is deposited to have the difference corresponding to the desired ratio. Therefore, the light-emitting layer (film), which is obtained when each of the film-forming components are deposited, is continuously grown with maintaining the difference corresponding to the desired ratio, such that the phase separation of each of the film-forming components does not occur, whereby each of the film-forming components is uniformly mixed with a desired ratio (difference). Therefore, the light-emitting layer obtained in this way is excellent in a light-emitting characteristic.

Further, in the light-emitting material, when the film-forming components are composed of two kinds of components, and the desired ratio of each of the film-forming components in the light-emitting layer to be formed is x:y, where x>y, the saturated concentration ratio of the film-forming components in the solution at a predetermined temperature is preferably (x±0.2x):y.

As described above, the saturated concentration ratio of each of the film-forming components at a predetermined temperature is set within about ±20% with respect to the desired ratio of each of the film-forming components. Therefore, for example, the drying temperature is set to be slightly lower than the predetermined temperature, whereby it is possible to make the ratio of each of the film-forming components during the time of deposition nearly equal to the desired ratio.

Further, in the light-emitting material, it is preferable that the film-forming components are composed of a host component and a guest component in a phosphorescent material.

When the light-emitting material is made of the phosphorescent material, it is possible to realize a more highly efficient light-emission. Therefore, in the case where the light-emitting layer of the organic EL apparatus is formed by using the light-emitting material, the light emission characteristic of the obtained organic EL apparatus can be enhanced.

Further, it is preferable that the light-emitting material be used for film formation by a liquid droplet ejection method.

Here, since the film formation by the liquid droplet ejection method such as the inkjet method is possible, it is possible to selectively distribute only the needed amount of the light-emitting material at desirable places. Therefore, it is possible to increase the productivity by excluding the patterning by using a lithography method or the like, thereby decreasing the production cost.

The method of manufacturing the organic EL apparatus according to the present invention comprises forming a film by using the light-emitting material, and forming a light-emitting layer by drying the formed film at a predetermined temperature.

According to the method of manufacturing the organic EL apparatus, since the above-described light-emitting material is used and the drying process is performed, the phase separation of each of the film-forming components does not occur in the light-emitting layer (film) obtained by the deposition of each of the film-forming components, whereby each of the film-forming components is uniformly mixed with a desired ratio (difference). Therefore, the light-emitting layer obtained in this way is excellent in the light-emitting characteristic.

An organic electroluminescent apparatus is obtained by the above-describe method. Therefore, it has an excellent light-emitting characteristic as described above.

### BRIEF DESCRIPTION OF THE DRAWINGS

The invention will be described with reference to the accompanying drawings, wherein like numbers reference like elements, and wherein:

FIG. 1 is a sectional view illustrating a process of a manufacturing method of an organic EL apparatus according to the present invention;

FIG. 2 is a sectional view illustrating a process of a manufacturing method of the organic EL apparatus, which follows up the process of FIG. 1;

FIG. 3 is a sectional view illustrating a process of a manufacturing method of the organic EL apparatus, which follows up the process of FIG. 2;

FIG. 4 is a sectional view illustrating a process of a manufacturing method of the organic EL apparatus, which follows up the process of FIG. 3;

FIG. 5 is a sectional view illustrating a process of a manufacturing method of the organic EL apparatus, which follows up the process of FIG. 4;

FIG. 6 is a sectional view illustrating a process of a manufacturing method of the organic EL apparatus, which follows up the process of FIG. 5; and

FIGS. 7A to 7C are views illustrating embodiments of an electronic apparatus.

### DETAILED DESCRIPTION OF EMBODIMENTS

Hereinafter, the present invention will be described in detail.

A light-emitting material according to the present invention is a film-forming material used for film formation by a liquid-phase method such as a liquid droplet ejection method and is a light-emitting material for forming a light-emitting layer in an organic EL device. Further, the light-emitting material is a solution composed of a plurality of film-forming components (solutes) and a solvent for dissolving the film-forming components.

The film-forming components are components constituting the light-emitting layer to be formed. Therefore, in the case where the light-emitting layer to be formed is composed of a plurality of components, the film-forming component in the solution (light-emitting material) is also composed of a plurality of film-forming components, as described above. Therefore, in order that the light-emitting layer composed of a plurality of components functions well as a light-emitting layer, the components needs to be uniformly mixed, as described above. Specifically, in the case where the light-emitting material is a phosphorescent material, the film-forming components correspond to two components, that is, a host component and a guest component, in the phosphorescent material, and both need to be uniformly mixed.

Here, the plurality of components (two components) are prepared with a ratio (weight ratio) substantially equal to the desired ratio of each of the film-forming components in the light-emitting layer to be formed and are dissolved in the solvent to form the solution. Specifically, in the light-emitting layer composed of the plurality of components, the light-emitting characteristic thereof differs depending on the ratio (weight ratio) of each of the components. Commonly, the light-emitting characteristic is enhanced to the almost at a specific ratio. Therefore, the specific ratio is defined as a ‘desired ratio’ in the present invention. Further, such desired ratio (specific ratio) can be easily obtained through experiments carried out beforehand or the like.

Further, in the present invention, the ratio of each of the film-forming components in the solution is made to be substantially equal to the desired ratio of each of the film-forming components in the light-emitting layer to be formed. However, ‘substantially equal’ means that a minute difference from the desired ratio, which occurs due to a measurement error of the material or the like, is within a permissible range in the present invention.

In the above-described light-emitting material, in the case where the desired ratio of each of the film-forming components in the light-emitting layer to be formed is different from each other, that is, in a case where the ratios of the film-forming components are not equal to each other, the ratios of the film-forming components in the light-emitting material (solute) are also not equal to each other. Therefore, the light-emitting material is prepared with the ratios of the film-forming components being different from each other.

In particular, the light-emitting material is prepared so that the saturated concentration of each of the film-forming components at the predetermined temperature is different corresponding to the difference in the ratio.

More specifically, when the film-forming components are composed of two kinds of components, that is, the host component and the guest component, in the phosphorescent material, and the desired ratio of each of the film-forming components in the light-emitting layer to be formed is x:y, where x>y, the saturated concentration ratio of each of the film-forming components at a predetermined temperature of the solution is (x±0.2x):y. Specifically, a solvent satisfying the above-mentioned condition with respect to the plurality of film-forming components forming a light-emitting layer is selected for use, such that the light-emitting material of the present invention is formed.

Here, as the film-forming components forming the light-emitting layer, various conventional phosphorescent materials composed of a host component and a guest component are suitable for use. Similarly, a fluorescent material formed as a two-component system may be used in the present invention.

Further, there is no specific limitation with respect to the solvent for dissolving the film-forming components. In particular, when the light-emitting material (solution) of the present invention is disposed by using the liquid droplet ejection method, such as an inkjet method, solvents having a boiling point of 200 to 400° C. in air are preferably used.

Specific examples of the solvent with a high boiling point include dodecyl benzene (boiling point, 331° C.), cyclohexyl benzene (boiling point, 240° C.), 1,2,3,4-tetramethyl benzene (boiling point, 203° C.), 3-isopropyl vinyl benzene (boiling point, 290° C.), 3-methylbiphenyl (boiling point, 272° C.), 4-methylbiphenyl (boiling point, 267° C.), p-anisylalcohol (boiling point, 259° C.), 1-methyl naphthalene (boiling point, 240 to 243° C.), 1,2,3,4-tetrahydronaphthalene (boiling point, 207° C.), or derivatives thereof may be exemplified, and they may be used as singly or in a mixture.

The light-emitting material of the present invention is prepared by using such a material having a high boiling point. Therefore, when the light-emitting material is ejected by the inkjet method or the like and is disposed at predetermined places, the solvent does not completely evaporate in a short time but remains in the organic thin film. Thereafter, a drying treatment such as heating and pressure-reduction is performed, whereby the solvent is totally dried, and the surface of the organic thin film (light-emitting layer) becomes extremely flat and exhibits superior adherence with respect to another film.

Further, the light-emitting material of the present invention may be applied to liquid-phase methods such as a spin coating method, other than the liquid droplet ejection method such as the inkjet method.

In the above-described light-emitting material, each of the film-forming components is prepared with a ratio substantially equal to the desired ratio and is dissolved in the solvent, thereby forming the solution. Therefore, when the solution (the light-emitting material) is dried at the predetermined temperature, the solvent in the solution is evaporated and the film-forming components in the solution reach saturated concentrations virtually simultaneously.

Specifically, since the saturated concentrations of the film-forming components in the solution at the predetermined temperature are different from each other corresponding to differences from the desired ratio of the film-forming components in the light-emitting layer to be formed, the film-forming components reach the saturated concentrations virtually simultaneously, not at different times. Then, each of the film-forming components is deposited with a difference corresponding to the desired ratio.

Therefore, the light-emitting layer (film), which is obtained by depositing the film-forming components, is continuously grown while maintaining the difference corresponding to the desired ratio, such that the phase separation of each of the film-forming components does not occur, whereby each of the film-forming components is uniformly mixed with a desired ratio (difference). Therefore, the light-emitting layer obtained in this way has excellent light-emitting characteristics.

Further, in the light-emitting material, when the film-forming components are composed of two kinds of components, the host component and the guest component, in the phosphorescent material, and the desired ratio of each of the film-forming components in the light-emitting material to be formed is x:y, where x>y, the saturated concentration ratio of each of the film-forming components in the solution at a predetermined temperature is preferably (x±0.2x):y. As described above, the saturated concentration ratio of each of the film-forming components at a predetermined temperature is set within about ±20% with respect to the desired ratio of each of the film-forming components. Therefore, for example, the drying temperature is set to be slightly lower than the predetermined temperature, whereby it is possible to make the ratio of each of the film-forming components during deposition nearly equal to the desired ratio. Thus, it is possible to improve the light-emitting characteristics of the obtained light-emitting layer.

### EXPERIMENTAL EXAMPLE

As the two-component system material, ‘Tris(4-phenylpiridinolato)Ir(III)’ (hereinafter, refer to as Ir(ppy)₃) and ‘4,4-dicarbazole-4,4-biphenyl’ (hereinafter, refer to as CBP), which is a phosphorescence-emitting material, were used. Here, among the compounds, Ir(ppy)₃ was a guest material and had the following structure:

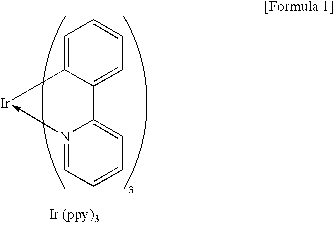

Further, CBP was a host material and had the following structure:

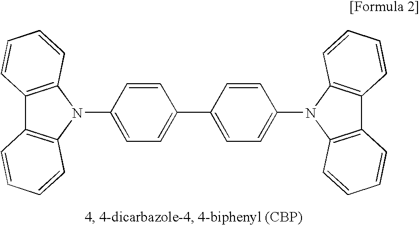

First, in a case where the two kinds of materials were used for the light-emitting layer of the organic EL element, a specific ratio in which the light-emitting characteristic was maximized, that is, ‘desired ratio’ in the present invention, was obtained as a ratio (weight ratio) between the two materials. Specifically, multiple kinds of solutions in which the ratio (weight ratio) between two materials were changed step-by-step were formed, each of the obtained solutions was film-formed using a spin coating method to thus form the light-emitting layer, and the organic EL elements were formed. Further, in such solutions, a solvent with a low boiling point was used. By doing so, when each of the solutions was applied by the spin coating method, the solvent was quickly vaporized, such that the solute materials (Ir(ppy)₃ and CBP) were deposited virtually simultaneously, whereby each of the light-emitting layers was formed without phase separation.

Each of the light-emitting layers was formed in this way, and the light-emitting characteristics of the obtained organic EL elements were measured. From the result of the measurement, we can found that the light-emitting characteristic was maximized when the weight ratio of Ir(ppy)₃ to CBP was 1 to 10. Here, the weight ratio is the ‘desired ratio’ in the present invention.

Next, Ir(ppy)₃ and CBP with the ‘desired ratio’ of 1:10 (weight ratio) were dissolved in a solvent. As the solvent, cyclohexyl benzene (hereinafter, refer to as CHB) having a relatively high boiling point (240° C.) was used for the purpose of applying the inkjet method. Since CHB has a relatively high boiling point, it was possible to obtain a flat thin film (light-emitting layer) as described above, when the solution using CHB as the solvent was ejected (coated) by an inkjet apparatus.

Ir(ppy)₃ and CBP were dissolved in the solvent (CHB), especially at room temperature (20° C.), with the weight ratio of the saturated concentration of Ir(ppy)₃ and CBP being 1:10. Specifically, the CBP dissolved more easily in the CHB at room temperature (20° C.) by a factor of about 10 compared to the Ir(ppy)₃.

Here, the above-described solution (light-emitting material) was prepared by adding the Ir(ppy)₃ and CBP with the ratio of 1:10 as the weight ratio to the CHB and by dissolving them in the CHB.

Next, the solution was ejected on a substrate by using the known inkjet apparatus. Then, the substrate was placed inside a vacuum drying furnace and was vacuum-dried (reduced pressure-dried) under a vacuum of 10⁻⁴ Torr at the predetermined temperature (room temperature (20° C.)), whereby the solvent was vaporized, and a thin film (light-emitting layer) was formed on the substrate.

The thin film (light-emitting layer) formed in this way was observed by an electron microscope or the like. From the result of the observation, we found that the Ir(ppy)₃ and CBP were uniformly mixed with a ratio of 1:10 on the entire thin film, and phase separation did not occur.

Further, the kind of solvent and the predetermined temperature being factors determining the saturated concentration were changed such that the saturated concentration ratio of the Ir(ppy)₃ and CBP at a predetermined temperature was changed step-by-step, and the thin film (light-emitting layer) was formed in the same way. Even when a solution in which the ratio of the saturated concentration ranges from 1:8 to 1:12 was used, we found that it was possible to form a thin film in which phase separation between Ir(ppy)₃ and CBP did not occur and they were uniformly mixed with substantially the same ratio to the desired ratio, by setting the drying temperature to be slightly lower than the predetermined temperature.

Hereinafter, a method of manufacturing the organic EL apparatus using the above-described light-emitting materials will be described.

The manufacturing method according to the present invention includes a partition wall forming process, plasma treatment process, a hole injection and transport layer forming process, a surface reforming process, a light-emitting layer forming process, a cathode forming process, and a sealing process.

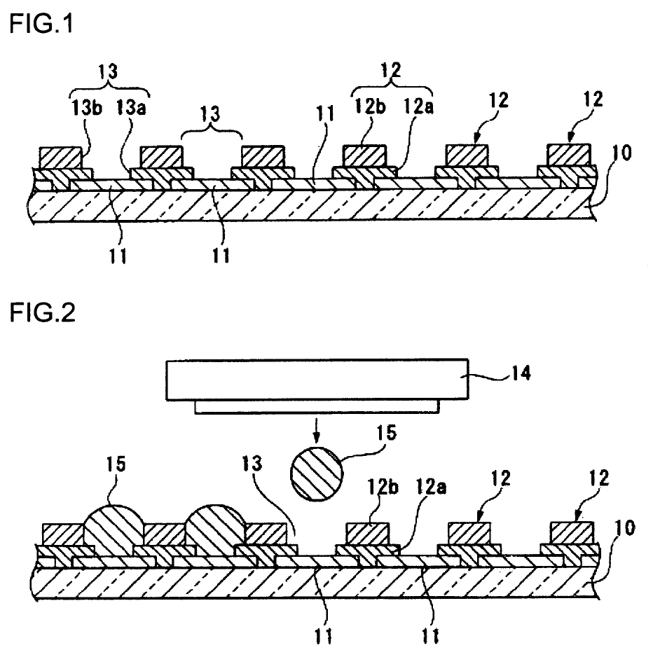

As shown in FIG. 1, in the partition wall forming process, inorganic bank layers 12a and organic bank layers 12b are sequentially laminated on transparent electrodes 11 formed of ITO or the like on a substrate 10 in which TFTs (not shown) or the like are preliminary formed as necessary, thereby forming bank layers (partition walls) 12 which partition each of pixel regions.

The inorganic bank layers 12a are formed by forming an inorganic film (not shown) such as SiO₂, TiO₂, SiN or the like on the entire surface of the substrate 10 and the transparent electrodes 11 by a CVD method, a sputtering method, a deposition method, and the like, and by patterning the inorganic film using an etching method or the like to form opening parts 13a in the pixel regions on the transparent electrodes 11. At this time, the inorganic bank layers 12a remain at the peripheral edges of the transparent electrodes 11. Further, the film thickness of the inorganic bank layers 12a is preferably 50 to 200 nm, and is more preferably 150 nm.

Next, an organic film (not shown) is formed on the entire surface of the substrate 10, the transparent electrodes 11, and the inorganic bank layers 12a. The organic film is formed by applying an organic resin such as acryl resin and polyimide resin, which is dissolved in a solvent, by a spin coating method, a dip coating method or the like. Then, the organic film is etched by a photolithography technology or the like to form the openings 13b, thereby forming the organic bank layers 12b. As shown in FIG. 1, the openings 13b of the organic bank layers 12b are preferably formed to be slightly wider than the openings 13a of the inorganic bank layers 12a. By doing so, the openings 13 penetrating through the inorganic bank layers 12a and the organic bank layers 12b are formed on the transparent electrode 11. Further, the shape of the openings 13 in a plan view may be a circle, an ellipse, or a quadrangle. However, in case of a quadrangle, since an ink compound has surface tension, it is preferable that the corners be rounded.

Next, in the plasma treatment process, areas showing ink-affinity and areas showing ink-repellency are formed on the surfaces of the bank layers 12. The plasma treatment process is classified broadly into a pre-heating process, an ink-affinity imparting process to make the entire surface show ink-affinity, an ink-repellency imparting process to make the organic material surface show ink-repellency, and a cooling process.

In the pre-heating process, the substrate 10 including the bank layers 12 is heated to a predetermined temperature. For example, the heating is performed by attaching a heater to a stage on which the substrate 10 is mounted in a plasma treatment chamber, and the substrate 10 on the stage is heated to a temperature of 70 to 80° C. by the heater. Due to the pre-heating, even though the plasma treatment is continuously performed on a plurality of substrates, it is possible to keep the plasma treatment conditions substantially constant just after the start-up of the treatment and just before the end of the treatment. Therefore, it is possible to make the bank layers 12 on the substrates 10 have a uniform affinity with respect to the ink compound, whereby a display apparatus having uniform quality can be manufactured. Further, the substrate 10 is pre-heated, whereby the treatment time for the plasma treatment can be reduced.

In the ink-affinity imparting process, a plasma treatment in which oxygen is used as a reaction gas (O₂ plasma treatment) is performed in air. Specifically, the substrate 10 including the bank layers 12 is disposed on a sample stage including a built-in heater, and oxygen in the plasma state is irradiated onto the substrate 10. The O₂ plasma treatment is performed under certain conditions, for example, a plasma power of 100 to 800 kW, an oxygen flow rate of 50 to 100 cc/min, a substrate transport speed of 0.5 to 10 mm/sec, and a substrate temperature of 70 to 90° C. By such O₂ plasma treatment, hydroxyl radicals are introduced to the exposed surfaces of the transparent electrodes 11 and the inorganic bank layers 12a, and the entire surface of the organic bank layers 12b, whereby ink-affinity is imparted thereto.

Next, in the ink-repellency imparting process, a plasma treatment (CF₄ plasma treatment) in which tetrafluoro methane (carbon tetrafluoride) is used as a reaction gas is performed in air. Specifically, the substrate 10 including the bank layers 12 is disposed on the sample stage including the built-in heater, and tetrafluoro methane (carbon tetrafluoride) in the plasma state is irradiated onto the substrate 10. The CF₄ plasma treatment is performed under certain conditions, for example, a plasma power of 100 to 800 kW, a tetrafluoro methane (carbon tetrafluoride) flow rate of 50 to 100 SCCM, a substrate transport speed of 0.5 to 10 mm/sec, and a substrate temperature of 70 to 90° C. Further, the treatment gas is not limited to tetrafluoro methane (carbon tetrafluoride): other fluorocarbon-based gases may be used. By such CF₄ plasma treatment, fluorine radicals are introduced to the organic bank layers to which the ink-affinity has been imparted in the ink-affinity imparting process, whereby ink-repellency is imparted thereto. In the organic material such as the acryl resin and polyimide resin, which constitutes the organic bank layers 12b, hydroxyl radicals are easily substituted with fluorine radicals by irradiating the fluorocarbon in a plasma state thereto, whereby the organic material can show ink-repellency. On the other hand, the exposed surfaces of the transparent electrodes 11 and the inorganic bank layers 12a also receive an effect caused by the CF₄ plasma treatment in some degree. However, it does not affect the affinity.

Next, in the cooling process, the substrate 10 heated for the purpose of the plasma treatment is cooled down to room temperature. Specifically, for example, the substrate 10 to which the plasma treatment has been performed is disposed on a water-cooling-type plate and is cooled down. The substrate 10 to which the plasma treatment has been performed is cooled down to room temperature or a predetermined temperature (for example, a controlled temperature at which the inkjet process is performed), whereby it is possible to perform the next hole injection and transport layer forming process at a constant temperature. Hereby, when a liquid-phase material including the material for the hole injection and transport layer is ejected by the inkjet method, it is possible to continuously eject liquid droplets at a constant volume and to uniformly form the hole injection and transport layer.

In the plasma treatment process, the O₂ plasma treatment and the CF₄ plasma treatment are sequentially performed on the inorganic bank layers 12a and the organic bank layers 12b, which are composed of different materials from each other, whereby it is possible to easily form ink-affinity areas and ink-repellency areas on the bank layer 12.

Next, in the hole injection and transport layer forming process, a liquid-phase material (an ink composite) 15 including the hole injection and transport layer material is ejected to the openings 13 on the transparent electrodes 11 by the inkjet method, and the drying treatment and the heating treatment are performed, thereby forming the hole injection and transport layer 16. Further, processes after the hole injection and transport layer forming process are preferably performed under an inert atmosphere, such as nitrogen atmosphere or argon atmosphere, without water and oxygen. As shown in FIG. 2, the liquid-phase material 15 (ink composite) including the hole injection and transport material is filled into an inkjet head 14, an ejection nozzle of the inkjet head 14 is disposed facing to the openings 13, the liquid-phase material 15, whose liquid volume of one droplet is controlled, is ejected onto each of the transparent electrodes 11 from the inkjet head 14 while moving the inkjet head 14 and the substrate 10 relative to each other.

Here, as the liquid-phase material 15, an ink composite in which, for example, a polythiophene derivative such as polyethylene dioxythiophene (PEDOT) and a mixture such as polystylene sulfonic acid (PSS) are dissolved in a polarized solvent can be used. As the polarized solvent, for example, isopropyl alcohol (IPA), butanol, γ-butyroloctone, N-methylpyrrolidone (NMP), 1,3-dimethyl-2-imidazolidinone (DMI) and derivatives thereof, and glycolethyl ether such as carbitol acetate and butyl carbitol acetate can be exemplified. Further, as the material for the hole injection and transport layer 16, the same material may be used with respect to each of light-emitting layers of red (R), green (G), and blue (B), or the material may be changed for each of the R, G, and B light-emitting layers.

The ejected liquid-phase material 15 is spread on the transparent electrode 11 and the inorganic bank layer 12a of the opening 13, each of which has undergone the ink-affinity treatment. Further, even though the liquid-phase material 15 is ejected onto the organic bank layers 12b, which deviated from the predetermined ejection position, the organic bank layer 12b does not get wet by the liquid-phase material 15, and the liquid-phase material 15 dropped thereto falls into the opening 13.

The ejection amount of the liquid-phase material 15 is determined depending on the size of the opening 13, the thickness of the hole injection and transport layer to be formed, the concentration of the hole injection and transport layer material in the liquid-phase material 15, and the like. Further, the liquid-phase material 15 may be ejected all at once, or it may be ejected in several batches into the same opening 13. In this case, the amounts of liquid-phase material 15 ejected each time may be equal to each other, or the amount may be different for every ejection. Further, the liquid-phase material 15 may be ejected into the same place in the opening 13, or it may be ejected onto different places in the opening 13 for every ejection.

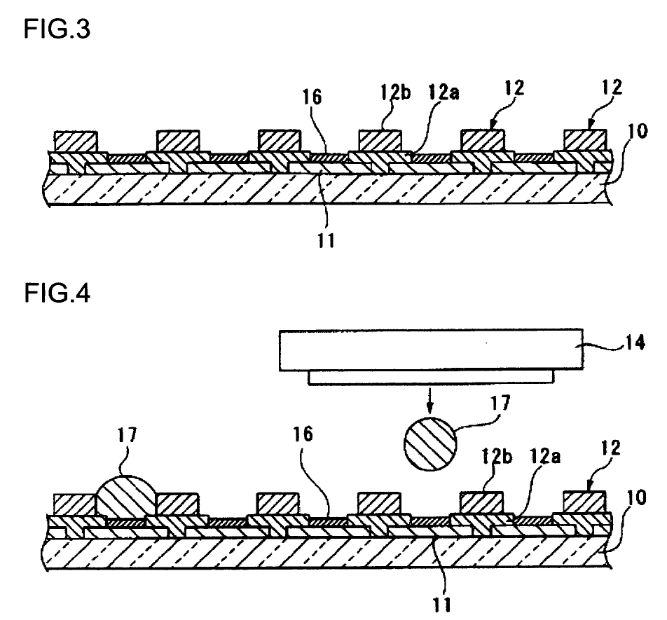

Next, as shown in FIG. 3, the liquid-phase material 15, after being ejected, is dried and the polarized solvent included in the liquid-phase material 15 is vaporized, thereby forming the hole injection and transport layer 16. This drying process is performed, for example, in nitrogen atmosphere, at room temperature, and at a pressure of 133.3 Pa (1 Torr). If the pressure is too low, the liquid-phase material 15 is suddenly vaporized, which is undesirable. Further, a small amount of the liquid-phase material 15 remains attached to a peripheral wall surface of the bank 12. However, when the temperature exceeds room temperature, the vaporization speed of the polarized solvent becomes higher, such that the amount of material remaining attached becomes excessive. Therefore, the temperature of the drying treatment is preferably set to room temperature or less. After the drying treatment, a heat treatment in nitrogen, more preferably in a vacuum, at 200° C., for 10 minutes is performed, such that the polarized solvent or water remaining in the hole injection and transport layer 16 is preferably removed.

In the above-described hole injection and transport layer forming process, the ejected liquid-phase material 15 is applied to the exposed surface of the ink-affinity transparent electrode 11 and the inorganic bank layer 12a, and is not attached to the organic bank layer 12b which has undergone the ink-repellency treatment, such that even if the liquid-phase material 15 is ejected by mistake onto the organic bank layer 12b, the liquid-phase material 15 dropped thereto falls onto the exposed surface of the transparent electrode 11 and the inorganic bank layer 12a. Therefore, the hole injection and transport layer 16 can be reliably formed on the transparent pixel electrode 11.

Next, in the light-emitting layer forming process, the above-described light-emitting material 17 according to the present invention is used as the ink composite and is ejected onto the hole injection and transport layer 16 by the inkjet method, as shown in FIG. 4. Further, as the light-emitting material for forming the light-emitting layer, the above-described light-emitting material according to the present invention is used with respect to all materials (ink composites) corresponding to each of the red color (R), the green color (G), and the blue color (B). Instead of this, a single component-based light-emitting material, for example, fluorescence emitting material (fluorescent material) which has been used heretofore, can be used with respect to one or two kinds of material among all of the materials.

As the single component-based light-emitting material, a fluorine-based high molecular derivative, a (poly) paraphenylene vinylene derivative, a polyphenylene derivative, a polyfluorene derivative, a polyvinyl carbazole, a polythiophene derivative, a perylene-based pigment, a coumarin-based pigment, and a rhodamine-based pigment can be used.

The light-emitting material 17 is ejected onto the hole injection and transport layer 16, and the drying treatment is performed for every light-emitting material, such that the light-emitting layers 18a, 18b, and 18c are sequentially formed, as shown in FIG. 5. In the drying treatment, in the case where the above-described light-emitting material according to the present invention is used as the light-emitting material, the drying treatment is performed by setting the predetermined temperature according to the present invention as the drying temperature, thereby forming the light-emitting layers 18a, 18b, and 18c. Since the drying treatment is performed in this way, the light-emitting layer 17 formed from the light-emitting material according to the present invention is formed so that the film-forming components (solutes) are uniformly mixed with a desirable compound ratio without causing phase separation thereof, as described above. Specifically, in the inside of a single pixel (bank layer 12), the film-forming components are uniformly mixed without irregularity. Further, at the time of the drying process, in the case where the predetermined temperature is room temperature, the light-emitting layers 18a, 18b, and 18c can be quickly and uniformly formed by adopting vacuum drying or reduced pressure drying, not heat drying.

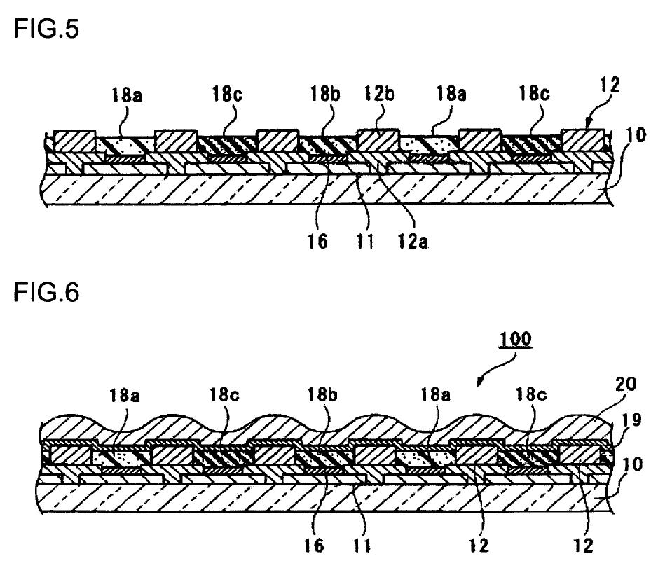

Next, in the cathode forming process, the cathode 19 is formed on the entire surface of the light-emitting layers 18a, 18b, and 18c, and the organic bank layers 12b, as shown in FIG. 6. The cathode 19 may be formed by laminating a plurality of materials. For example, it is preferable that the material near the light-emitting layer among the plurality of laminated materials be composed of a material such as Ca and Ba, which has a low work function. Further, it is preferable that the upper side (sealing side) is composed of Al film, Ag film, Mg/Ag laminated film or the like, which has a work function higher than that of the cathode layer of the lower side (light-emitting layer side). Further, the thickness of the cathode is preferably in the range of 100 to 1000 nm, and more preferably 200 to 500 nm. The cathode (cathode layer) is preferably formed by a deposition method, a sputtering method, a CVD method, or the like. Specifically, in the case of the deposition method, damage caused by heating the light-emitting layers 18a, 18b, and 18c can be prevented, which is advantageous. Further, a protective layer such as SiO, SiO₂, SiN, or the like, which prevents oxidization from being generated, may be formed on the cathode 19.

Finally, in a sealing process, a sealing material composed of a heat-curable resin or an ultraviolet-curable resin is applied onto the entire surface of the cathode 19, thereby forming a sealing layer 20. Further, a sealing substrate (not shown) is laminated onto the sealing layer 20. The sealing process is preferably performed in an inert atmosphere of nitrogen, argon, helium, or the like. In a case where it is performed in air, when a defect such as a pin hole is formed in a reflective layer, water or oxygen penetrates into the cathode 19 through the defect portion and the cathode 19 can be oxidized. Therefore, this is undesirable. In this way, an organic EL apparatus shown in FIG. 6 is obtained.

In the organic EL apparatus 100 obtained in this way, the above-described light-emitting layer 17 is formed so that each of the film-forming components (solutes) are uniformly mixed with a desirable compound ratio without phase separation thereof, whereby the organic EL apparatus 100 has excellent light-emitting characteristics.

Further, the organic EL apparatus according to the present invention is not limited to the above-described embodiment, and various modifications can be made. For example, in the above-described embodiment, the light-emitting layers of R, G, and B are included for full-color display. However, it is possible to emit only a single color light among all the colors and to use it as a light source. Further, in the case where the organic EL apparatus 100 is used as a light source, it is possible to make the light-emitting layers 18a, 18b, and 18c of R, G, and B emit at the same time, and to use them as a white light source emitting white light.

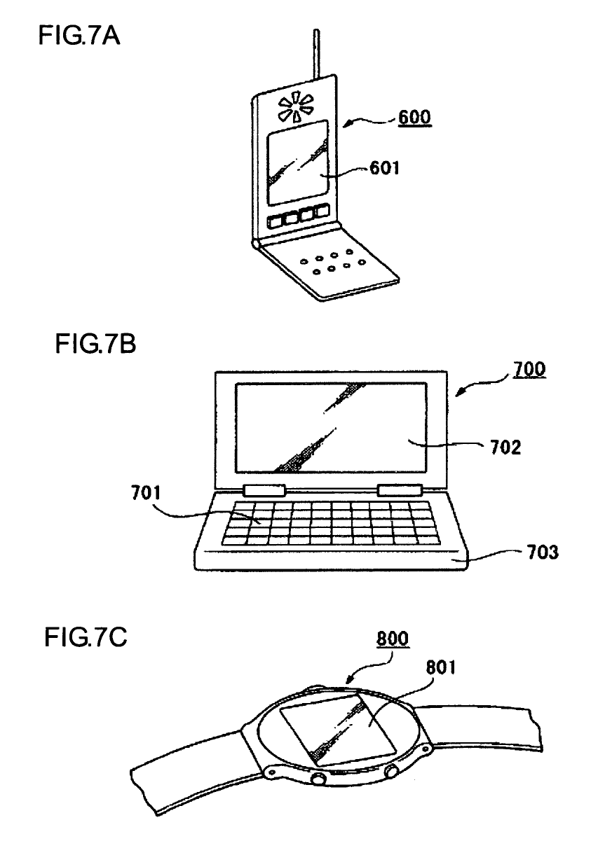

Next, specific examples of an electronic apparatus including the organic EL apparatus 100 as a display part will be described. FIG. 7A is a perspective view illustrating an example of a portable telephone. In FIG. 7A, reference numeral 600 indicates a main body of the portable telephone, and reference numeral 601 indicates the organic EL apparatus serving as a display unit. FIG. 7B is a perspective view illustrating an example of a portable information processing apparatus, such as a word processor, a personal computer, or the like. In FIG. 7B, reference numeral 700 indicates an information processing apparatus, reference numeral 701 indicates an input unit such as a keyboard, reference numeral 703 indicates the main body of the information processing apparatus, and reference numeral 702 indicates the organic EL apparatus serving as a display unit. FIG. 7C is a perspective view illustrating an example of a wristwatch-type electronic apparatus. In FIG. 7C, reference numeral 800 indicates a main body of the wristwatch, and reference numeral 801 indicates the organic EL apparatus serving as a display unit. According to the present embodiments, it is possible to provide an electronic apparatus including a display apparatus having excellent light-emitting characteristics.

What is claimed is:

1. A light-emitting material which is a film-forming material used for film formation by a liquid-phase method and which is a light-emitting material for forming a light-emitting layer, comprising:
a plurality of film-forming components; and
a solvent for dissolving the film-forming components, the light-emitting material being a solution,
wherein the ratio of each of the film-forming components in the light-emitting layer to be formed is different, and each of the film-forming components is prepared with a ratio substantially equal to the desired ratio and is dissolved in the solvent, and
saturated concentrations of each of the film-forming components in the solution at a predetermined temperature are different from each other corresponding to the difference in the desired ratio.

2. The light-emitting material according to claim 1,
wherein the film-forming components are composed of two kinds of components, and when the desired ratio of each of the film-forming components in the light-emitting layer to be formed is x:y, where x>y, the saturated concentration ratio of the film-forming components in the solution at a predetermined temperature is (x±0.2x):y.

3. The light-emitting material according to claim 1, wherein the film-forming components are composed of a host component and a guest component in a phosphorescent material.

4. The light-emitting material according to claim 1, wherein the light-emitting material is used for film formation by a liquid droplet ejection method.

5. A method of manufacturing an organic electroluminescent apparatus, comprising:
forming a film by using the light-emitting material according to claim 1, and
forming a light-emitting layer by drying the formed film at a predetermined temperature.

6. An organic electroluminescent apparatus obtained by the method according to claim 5.
